(19) United States
(12) Patent Application Publication
(10) Pub. No.: US 2023/0132047 A1
(43) Pub. Date: Apr. 27, 2023

(54) SWITCHED GRADIENT FIELD MEASUREMENT TECHNIQUES FOR SURFACE NMR

(71) Applicant: Vista Clara Inc., Mukilteo, WA (US)

(72) Inventors: David Walsh, Shoreline, WA (US); Elliot Grunewald, Seattle, WA (US); Darya Morozov, Mill Creek, WA (US)

(21) Appl. No.: 18/047,969

(22) Filed: Oct. 19, 2022

Related U.S. Application Data
(60) Provisional application No. 63/262,945, filed on Oct. 22, 2021.

(51) Int. Cl. G01V 3/14

(52) U.S. Cl. CPC G01V 3/14

(57) ABSTRACT

Switched gradient field measurement techniques for SNMR are disclosed, as well as hardware and software that implements the disclosed techniques. The disclosed techniques allow directly imaging groundwater and hydrogeologic parameters at high resolution in the near subsurface. The resulting technology redefines practical capabilities for hydrogeologic imaging and shallow groundwater mapping, ultimately improving our ability understand, manage, and respond to critical zone processes.

### CROSS-REFERENCE TO RELATED APPLICATIONS

This is a nonprovisional claiming priority under 35 U.S.C. § 119 of co-pending U.S. Provisional Patent Application No. 63/262,945, entitled “SWITCHED GRADIENT FIELD MEASUREMENT TECHNIQUES FOR SURFACE NMR”, filed on Oct. 22, 2021. The prior application is incorporated by reference herein in its entirety.

### STATEMENT OF GOVERNMENT SUPPORT

This invention was made in part with Government support under Agreement DE-SC0019671 awarded by the U.S. Department of Energy. The Government has certain rights in this invention.

### BACKGROUND

Nuclear Magnetic Resonance (NMR) systems have been in use for many years and can be used to provide imaging and/or analysis of a sample being tested. Various different types of NMR include medical NMR, often referred to as Magnetic Resonance Imaging (MRI), and Surface NMR (SNMR), which provides geophysical techniques for detecting subsurface liquids in the earth's crust. While there is some overlap in the technologies that may be applied in MRI and SNMR, the samples being measured and the environments in which measurements are performed are different, leading to many differences in the technologies applied.

In SNMR, improving detection and spatial resolution of groundwater at shallow depths in order to map groundwater and hydrogeologic properties in the subsurface presents a particular challenge. The shallow subsurface is the domain of many critical processes including contaminant transport, nutrient cycling, cryosphere thaw, and hydromechanical soil failure. All these groundwater processes have direct impacts on human health, ecosystem health, and the world economy, but this critical zone of the subsurface is hidden from direct view. Acquiring observational data typically involves disruptive investigations: drilling wells, extracting core and fluid samples, or embedding sensors. These conventional approaches are costly and provide limited sampling over areas that are spatially heterogeneous.

Geophysical methods have proven to be a valuable toolkit for investigating water in the critical zone. These methods allow non-invasive and efficient mapping of subsurface variations at high spatial and temporal resolutions. Common geophysical methods include, for example, electrical resistivity tomography, ground-penetrating radar, and seismic reflection. The images produced by these techniques can be detailed in structure, however, they reflect the physical parameters that can be most easily measured (e.g. electrical conductivity, permittivity, density, etc.). These physical parameters are affected by many variables (e.g. fluid chemistry, mineral chemistry, clay content) and so cannot be uniquely related to groundwater and hydrogeologic variability.

SNMR detects the hydrogen nucleus in water and is the only geophysical method that can provide direct detection of groundwater, including sensitivity to hydrogeologic properties including pore size, total/effective porosity and permeability. To date, however, SNMR has primarily been implemented for coarse resolution of groundwater aquifers. Although surface NMR uses the same physics as medical MRI, the paradigms used for SNMR imaging have been rudimentary in comparison, due to challenges that are unique to SNMR, resulting in substantial limits to resolution, even for shallow investigations.

### SUMMARY

Technologies disclosed herein include switched gradient field measurement techniques for SNMR, as well as hardware and software that implements the disclosed techniques. The disclosed techniques allow directly imaging groundwater and hydrogeologic parameters at high resolution in the near subsurface. The resulting technology redefines practical capabilities for hydrogeologic imaging and shallow groundwater mapping, ultimately improving our ability understand, manage, and respond to critical zone processes. Further aspects and variations are discussed in detail below.

### BRIEF DESCRIPTION OF THE DRAWINGS

Various features and attendant advantages of the disclosed technologies will become fully appreciated when considered in conjunction with the accompanying drawings, in which like reference characters designate the same or similar parts throughout the several views, and wherein:

FIG. 1 is a schematic illustration of example switched gradient field SNMR equipment deployed on the Earth surface, in accordance with various aspects and embodiments of the subject disclosure.

FIG. 2A illustrates a first example SNMR pulse sequence and resulting SNMR response that can be observed using the equipment introduced in FIG. 1, in accordance with various aspects and embodiments of the subject disclosure.

FIG. 2B illustrates a second example SNMR pulse sequence and resulting SNMR response that can be observed using the equipment introduced in FIG. 1, in accordance with various aspects and embodiments of the subject disclosure.

FIG. 2C illustrates a third example SNMR pulse sequence and resulting SNMR response that can be observed using the equipment introduced in FIG. 1, in accordance with various aspects and embodiments of the subject disclosure.

FIG. 2D illustrates a fourth example SNMR pulse sequence and resulting SNMR response that can be observed using the equipment introduced in FIG. 1, in accordance with various aspects and embodiments of the subject disclosure.

FIG. 2E illustrates a fifth example SNMR pulse sequence and resulting SNMR response that can be observed using the equipment introduced in FIG. 1, in accordance with various aspects and embodiments of the subject disclosure.

FIG. 2F illustrates a sixth example SNMR pulse sequence and resulting SNMR response that can be observed using the equipment introduced in FIG. 1, in accordance with various aspects and embodiments of the subject disclosure.

FIG. 3 illustrates an example comparison of acquisition methods, in accordance with various aspects and embodiments of the subject disclosure.

FIG. 4 illustrates example hardware that can be used to implement SNMR electronics and switched gradient and prepolarization electronics, in accordance with various aspects and embodiments of the subject disclosure.

FIG. 5A illustrates an example coil configuration, in accordance with various aspects and embodiments of the subject disclosure.

FIG. 5B illustrates another example coil configuration, in accordance with various aspects and embodiments of the subject disclosure.

FIG. 5C illustrates another example coil configuration, in accordance with various aspects and embodiments of the subject disclosure.

FIG. 5D illustrates another example coil configuration, in accordance with various aspects and embodiments of the subject disclosure.

FIG. 5E illustrates another example coil configuration wherein injectable electrode(s) are used in place of a switchable coil, in accordance with various aspects and embodiments of the subject disclosure.

FIG. 5F illustrates another example coil configuration wherein a switchable coil and a SNMR coil are elliptical in shape, and wherein the SNMR coil is smaller than the switchable coil, in accordance with various aspects and embodiments of the subject disclosure.

FIG. 5G illustrates another example coil configuration wherein a switchable coil and a SNMR coil are not coplanar, in accordance with various aspects and embodiments of the subject disclosure.

FIG. 6 illustrates components of surface NMR kernel for a gradient-adiabatic experiment, in accordance with various aspects and embodiments of the subject disclosure.

FIG. 7 illustrates calculation of the 3D Kernel without phase encoding as the product of a sensitivity map and an excitation map, in accordance with various aspects and embodiments of the subject disclosure.

FIG. 8 illustrates aspects of an example SNMR system, in accordance with various aspects and embodiments of the subject disclosure.

FIG. 9 is a block diagram illustrating an example computer, in accordance with various aspects and embodiments of the subject disclosure.

### DETAILED DESCRIPTION

Prior to explaining embodiments of the invention in detail, it is to be understood that the invention is not limited to the details of construction or arrangements of the components and method steps set forth in the following description or illustrated in the drawings. The invention is capable of other embodiments and of being practiced and carried out in various ways. Also, it is to be understood that the phraseology and terminology employed herein are for the purpose of the description and should not be regarded as limiting.

### SNMR in Porous Media

SNMR measurements probe the response of hydrogen in groundwater (or other fluids) to a magnetic field perturbation, giving information about the quantity of fluid and its pore environment. In the presence of a background field, B₀, the nuclear spins of the hydrogen will be polarized creating a net nuclear magnetization M₀ parallel to B₀. The magnitude of the background B₀ field determines the degree of polarization (magnitude of M₀) and determines the level or frequency at which the hydrogen can absorb and emit energy. This frequency, f₀=γ|B₀|, is known as the Larmor frequency and γ is the gyromagnetic ratio of hydrogen. By transmitting a second oscillating magnetic field B₁ at the Larmor frequency, the magnetization is excited into a higher energy state away from the B₀-axis. In this excited state, the magnetization will precess about the background field at the Larmor frequency and will eventually relax back to equilibrium alignment. This precession can be detected on an induction coil as a voltage oscillating at the Larmor frequency, allowing quantification of the magnetization (which corresponds to fluid content) and relaxation time constant.

The amplitude of a detected SNMR signal is directly correlated with the quantity of fluid (saturated porosity) and the relaxation time is correlated with the dimension of the pore space. Given that porosity and pore size are parameters controlling flow, NMR amplitude and decay characteristics have been used in oil field NMR well logging to also estimate permeability. With the development of portable borehole NMR logging tools, similar relationships have also been developed for aquifer sediments.

### Geophysical SNMR

Surface NMR (SNMR) is an established geophysical method allowing non-invasive measurement of, e.g., groundwater NMR signals. The first simple SNMR systems were developed in the late 1980's with a wave of 2^{nd} generation improvements to hardware and interpretation schemes beginning the mid 2000's.

Conventional surface NMR measurements utilize the Earth's geomagnetic field as B₀. In the weak geomagnetic field (Bₑₐᵣₜₕ˜50 μT), the polarized magnetization M₀ is small and f₀ is low (˜2 kHz). To excite groundwater, a B₁ field is generated by routing a large AC current pulse through a wire surface loop, typically 10-150 meters (m) in diameter. The resulting signals are detected as a voltage on the loop. Due to the low magnitude of B₀, signal levels can be very small, typically on the order of tens or hundreds of nanovolts. As such, the measurement is generally signal-to-noise constrained, requiring long measurement times and advanced noise reduction schemes, such as multi-channel adaptive noise cancellation. Given appropriate site conditions, studies comparing SNMR to NMR logging and direct hydrogeologic measurements have proven SNMR to be a valuable tool for aquifer characterization.

While SNMR has seen increased adoption for aquifer characterization, the technology has been challenged to provide high-resolution imaging, particularly when it is necessary to localize targets at shallow depths. Coarse depth profiling is conventionally achieved by “soundings” where an “on-resonance” B₁ pulse is transmitted (f_{Tx}=f₀), and the experiment is repeated using varied B₁ amplitudes. A large pulse preferentially excites deeper targets, and a smaller pulse excites shallower targets, however, the excitation patterns in depth are oscillatory and not well localized. A forward model of the excitation profile can be used to mathematically invert for signals as a function of depth, but because the kernel functions can be smeared, the resolution is fundamentally limited, with a particular inability to distinguish thin high-porosity layers from thick low-porosity layers.

Lateral resolution is controlled by the coil dimension. A smaller coil has a more focused footprint, but shrinking the diameter dramatically limits sensitivity. If the coil diameter is reduced by a factor of three, the volume of detected water below the coil is decreased by a factor of 3³=27. As such the effective signal measured by a 3-meter coil may be 90% smaller than that for a 10 meter coil, and signals can become too small for robust detection.

Recent advancements have shown promising results for increasing signal in detection coils. Adiabatic surface NMR pulses uniformly excite the full hemisphere below the coil, resulting in a larger signal amplitude compared to the oscillatory excitation of on-resonance pulses. Prepolarization can impose a large prepolarizing field Bₚ>>Bₑₐᵣₜₕ before the main measurement resulting in a very large nuclear magnetization in the direction of Bₚ. By shutting off Bₚ in a fast and controlled manner, the magnetization is “adiabatically” returned to equilibrium providing a larger available magnetization (e.g. up to ten times greater signal amplitudes) for subsequent experiments. Both prepolarization and adiabatic excitation can increase signal detection.

### MRI and Gradient Fields

MRI uses the same essential physics mentioned above, using different equipment configurations in a different, more controlled environment. In MRI, superconducting electromagnets create a uniform B₀ field (1-7T, f₀=40-300 MHz) and coils produce B₁ fields to excite and measure hydrogen in the body's tissue. But the addition of an elegantly simple concept, gradient fields, enables MRI to precisely resolve hidden tumors and networks of blood vessels.

Specialized coils create a third field, the gradient field G that can be imposed on top of the static B₀ field. For a gradient that increases in the x-direction, the total field varies as B₀+G(x) and the resonant frequency varies as f(x)=f₀+γG(x). This equation establishes a direct link between the frequency response of the tissue and its physical location, a link which can be exploited in several ways. If the gradient is on during excitation, the pulse can be tuned to a frequency that excites a corresponding x-slice. If the gradient is turned on for a short period after excitation, a unique phase shift pattern is encoded across the target. And if the gradient is cycled during the readout, the signal will be frequency encoded such that the signal is exactly the Fourier transform of the target projected in the gradient direction. Different MRI imaging protocols use these methods in varied combinations, but always rely upon gradient fields and Fourier transform mathematics to yield high-resolution images.

In geophysics, we lack many advantages available in MRI: superconducting magnets are not field portable, we cannot surround our target on all sides, and our trickiest targets may even have magnetic constituents. But if we can capitalize on even a fraction of the gradient imaging methodologies from MRI, we can transform the capabilities of SNMR.

### Technical Approach

The disclosed SNMR systems inventively combine switched fields to significantly enhance detection and resolution of groundwater and other underground fluids. The technology is supported by 1. Innovative acquisition and signal processing imaging methods including gradient encoding, enhanced polarization, and modulated pulses, and 2. Advanced electronics and surface coil geometries to support flexible generation of high-power, rapidly switched DC fields in a portable configuration for efficient surveying.

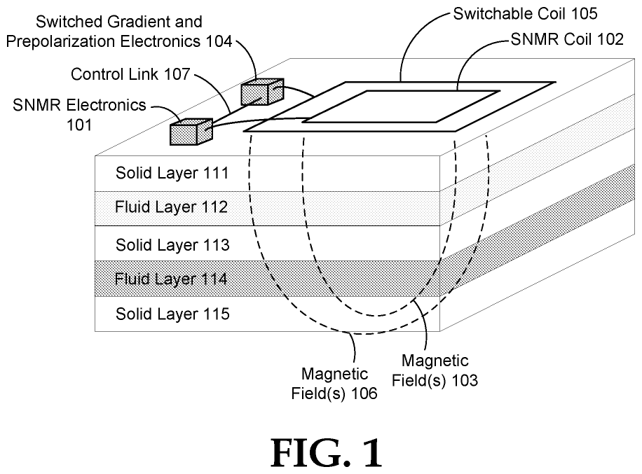

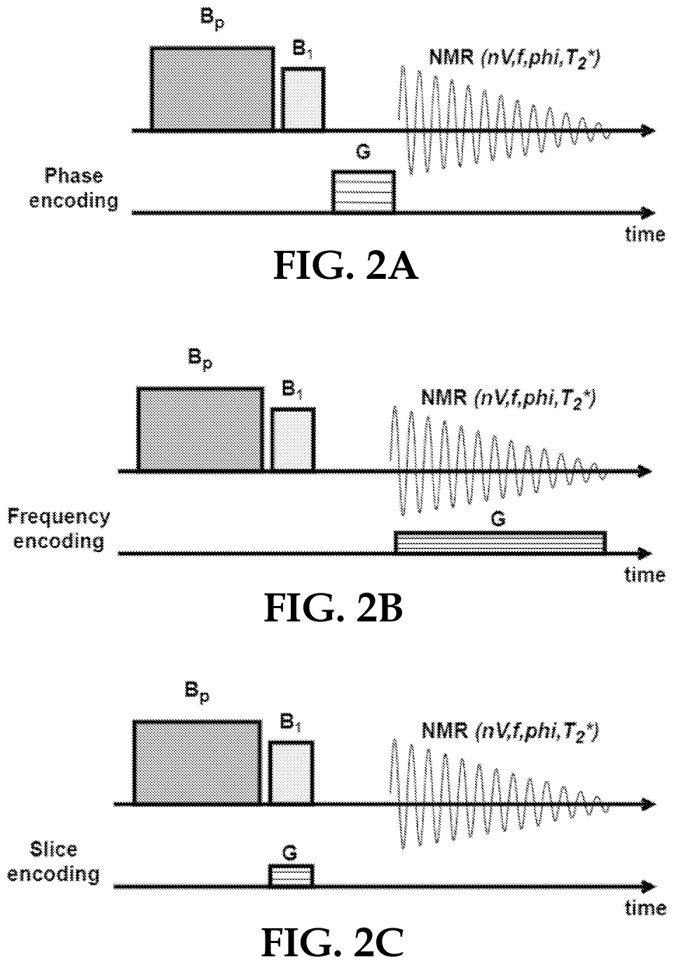

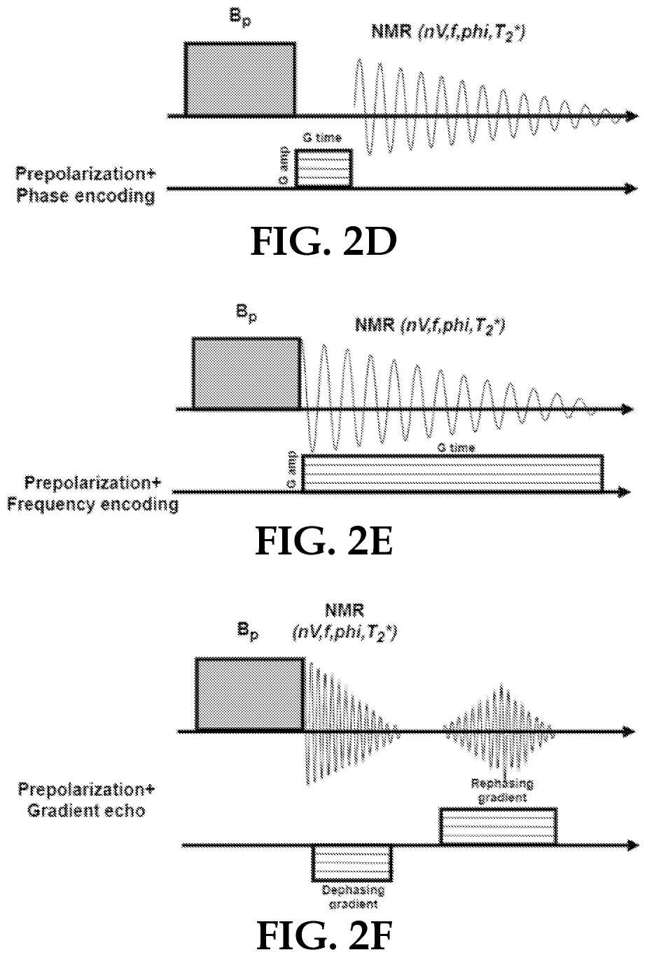

The proposed instrumentation and measurement paradigm are shown in FIG. 1 and FIGS. 2A, 2B, 2C, 2D, 2E and 2F. FIG. 1 is a schematic illustration of example switched gradient field SNMR equipment deployed on the Earth surface, in accordance with various aspects and embodiments of the subject disclosure. FIG. 1 includes SNMR electronics 101 coupled with an SNMR coil 102, wherein the SNMR coil 102 can optionally generate magnetic field(s) 103 that penetrate the various subsurface layers, e.g., solid layer 111, fluid layer 112, solid layer 113, fluid layer 114, and solid layer 115. FIG. 1 further includes switched gradient and prepolarization electronics 104 coupled with a switchable coil 105, wherein the switchable coil 105 can generate magnetic field(s) 106 that penetrate the various subsurface layers 111-115. In some embodiments, the apparatus illustrated in FIG. 1 can be applied in other SNMR measurement settings, e.g., on or in engineered flow management structures such as dams, levees, canals, well casings, pipelines, annular spaces between well casings or underground pipelines and undisturbed earth formations, slurry walls, grout curtains, or retaining walls.

FIGS. 2A, 2B, 2C, 2D, 2E, and 2F illustrate example SNMR pulse sequences and resulting SNMR responses that can be observed using the equipment introduced in FIG. 1, in accordance with various aspects and embodiments of the subject disclosure. FIG. 2A uses a phase encoding approach. In FIG. 2A, the switched gradient and prepolarization electronics 104 and switchable coil 105 can first be activated to generate a prepolarizing field Bₚ. The prepolarizing field Bₚ is a first magnetic field of the magnetic field(s) 106 illustrated in FIG. 1. The SNMR electronics 101 and SNMR coil 102 can next be activated to generate an SNMR excitation pulse B₁. The SNMR excitation pulse B₁ is a magnetic field of the magnetic field(s) 103 illustrated in FIG. 1. The switched gradient and prepolarization electronics 104 and switchable coil 105 can next be activated to generate a gradient G. The gradient G is a second magnetic field of the magnetic field(s) 106 illustrated in FIG. 1. Finally, the NMR signal NMR (nV,f,phi,T₂*) resulting from the applied prepolarizing field Bₚ, excitation pulse B₁, and gradient G can be received via the SNMR electronics 101 and the SNMR coil 102, and the SNMR electronics 101 can process the NMR signal NMR (nV,f,phi,T₂*) in order to understand the properties of the layers 111-115.

FIG. 2B uses a frequency encoding approach. In FIG. 2B, the switched gradient and prepolarization electronics 104 and switchable coil 105 can first be activated to generate a prepolarizing field Bₚ. The prepolarizing field Bₚ is a first magnetic field of the magnetic field(s) 106 illustrated in FIG. 1. The SNMR electronics 101 and SNMR coil 102 can next be activated to generate an SNMR excitation pulse B₁. The SNMR excitation pulse B₁ is a magnetic field of the magnetic field(s) 103 illustrated in FIG. 1. The switched gradient and prepolarization electronics 104 and switchable coil 105 can next be activated to generate a gradient G. The gradient G is a second magnetic field of the magnetic field(s) 106 illustrated in FIG. 1. During the application of gradient G, an NMR signal NMR (nV,f,phi,T₂*) resulting from the applied prepolarizing field Bₚ, excitation pulse B₁, and gradient G can be received via the SNMR electronics 101 and the SNMR coil 102, and the SNMR electronics 101 can process the NMR signal NMR (nV,f,phi,T₂*) in order to understand the properties of the layers 111-115.

FIG. 2C uses a slice encoding approach. In FIG. 2C, the switched gradient and prepolarization electronics 104 and switchable coil 105 can first be activated to generate a prepolarizing field Bₚ. The prepolarizing field Bₚ is a first magnetic field of the magnetic field(s) 106 illustrated in FIG. 1. The SNMR electronics 101 and SNMR coil 102 can next be activated to generate an SNMR excitation pulse B₁. The SNMR excitation pulse B₁ is a magnetic field of the magnetic field(s) 103 illustrated in FIG. 1. During the application of the SNMR excitation pulse B₁, the switched gradient and prepolarization electronics 104 and switchable coil 105 can be activated to generate a gradient G. The gradient G is a second magnetic field of the magnetic field(s) 106 illustrated in FIG. 1. Finally, the NMR signal NMR (nV,f,phi,T₂*) resulting from the applied prepolarizing field Bₚ, excitation pulse B₁, and gradient G can be received via the SNMR electronics 101 and the SNMR coil 102, and the SNMR electronics 101 can process the NMR signal NMR (nV,f,phi,T₂*) in order to understand the properties of the layers 111-115.

With reference to the techniques illustrated in FIGS. 2A-2C, conventionally, a main coil such as the SNMR coil 102 is used to excite groundwater and to measure the resulting NMR precession as a voltage on the main coil. If the coil dimension or water volume is small, however, this resulting NMR signal voltage signal is very low amplitude and the old practice of varying B₁ provides little ability to discriminate or resolve neighboring water zones, e.g., fluid layers 112 and 114.

One aspect of FIG. 1 is a second coil 104 added around the main coil 102 with flexible electronics capable of generating high-power, precisely switched prepolarization and gradient fields. By varying the amplitude and timing of switched fields, not only can the signal amplitude be increased but the signal can be more precisely localized in space based on its amplitude, phase, and frequency content.

At the start of a measurement, a large current can be switched into the coil 104 for several seconds, creating a (Bₚ) field that polarizes fluids below the main coil 102. When Bₚ is switched off, shallow fluids in fluid layer 112 remain prepolarized with larger magnetization amplitude. The fluid in fluid layers 112 and 114 is then excited by transmitting a B₁ excitation pulse on the main coil 102. Rather than only relying on the B₁ pulse to localize signals, high-resolution localization can be achieved by applying imaging gradients. After the excitation pulse B₁, a DC current can be switched on, creating a static imaging gradient field (G). Hydrogen at different positions in the gradient field G, e.g., at fluid layers 112 and 114, will accumulate a different phase or frequency shift. In this way, the position of hydrogen relative to the gradient G is encoded at high-resolution into the NMR signal. This novel use of gradients improves on the conventional approach of surface NMR “soundings”, enabling the use of Fourier methods and a new dimension of spatial encoding for high-resolution imaging.

In a system such as illustrated in FIG. 1, prepolarization overcomes a limitation of very low signal amplitudes for measurements in Earth's field. In recent studies, multi-turn prepolarization coils have been shown to increase signal amplitude by an order of magnitude at depths of a few meters. This increase in signal not only supports the use of small coils, but also supports the proposed gradient imaging techniques, which benefit from a high signal-to-noise ratio. As shallower targets are more strongly prepolarized, spatial information can also be encoded by prepolarization.

Prepolarization can be an important component of the switched-field scheme, particularly when small loops are used to investigate small shallow targets. Small loops and small targets generally result in low signal amplitudes. Prepolarization increases the signal amplitude of shallow targets, but the incorporation of prepolarization with gradient coils has not previously been considered. Prepolarization can increase performance of switched-field methods in the very shallow subsurface, e.g., the upper 5 m of the subsurface.

Embodiments can select prepolarization coil properties such as dimensions and Amp turns, such that prepolarization fields are much stronger than the Earth's field within the detection coil's sensitive zone. The angle p between the prepolarization and Earth's field can be calculated within each subsurface voxel. This angle can determine the adiabaticity of a prepolarization shutoff. The prepopolarized magnetization factor at each given voxel can then be determined based on the voxel's angle p and an associated p-value from a Bloch lookup table.

Using gradient encoding with an adiabatic pulse preceded by prepolarization can produce signal values (and thus a signal to noise ratio) which are on the order of 10 times larger. This is an advantage of prepolarization and is particularly valuable for gradient encoded imaging. The sensitivity is particularly focused at shallow depths, indicating that the resolution for very shallow targets is increased.

Furthermore, adiabatic excitation pulses in surface NMR can uniformly excite the entire hemisphere below the coil 102. Considered alone, the broad excitation pattern of an adiabatic pulse does not provide localization in depth (e.g. compared to an on-resonance pulse). In approaches according to this disclosure, however, uniform excitation can beneficial because signals are obtained from the largest possible volume and are localized by gradient encoding.

Phase encoding according to FIG. 2A can be implemented by performing multiple measurements where a gradient G is imposed after the excitation pulse B₁ for a short time (milliseconds) before the resulting NMR signal is recorded. The amplitude of G can be varied between measurements. Signals from shallow water (fluid layer 112) experience a stronger field than signals from deeper water (fluid layer 114). The shallow signals thus accumulate a more rapid phase shift than the deep signals. Using the measured variation in amplitude and phase, the resulting NMR signal can thus be localized using Fourier transform relations and the known gradient geometry. An advantage of the phase encoding approach is that the phase of the resulting NMR signal is altered while the amplitude and T₂* decay time of the signal is undisturbed.

Frequency encoding according to FIG. 2B can be used independently or in combination with phase encoding, by turning on the switchable coil 105 during readout of NMR signals. In the simple instance of a linear gradient, the Fourier transform of the echo signal directly reflects the position of an NMR signal with respect to the gradient. Of course, in the instance of a surface coil 105 where the gradient is not linear, the gradient geometry must be considered. By encoding to frequency, the time series information from phase encoding is lost, but theoretically frequency encoding allows one dimensional imaging within a single measurement.

Slice-selective excitation according to FIG. 2C may also be combined with the above approaches of FIGS. 2A and 2B as an alternative to broad adiabatic excitation. If a gradient G is on during an excitation pulse B₁, a localized slice of the subsurface layers 111-115 can be excited where the resonant frequency γ(B₀+G(r)) is spanned by the frequency content of the excitation pulse B₁. Thus slice-selective excitation offers an additional modality for localization using the controlled gradient.

The techniques illustrated in FIGS. 2D, 2E, and 2F omit the use of an excitation pulse B₁. In example embodiments, surface NMR methods that use pre-polarization with fast non-adiabatic turn off can generate detectable free-induction decay (FID) NMR signals from near surface groundwater without requiring an excitation pulse B₁.

In general, the approaches illustrated in FIGS. 2D, 2E, and 2F can apply a DC current on a prepolarization coil 105 to generate a static field Bₚ. The static field Bₚ can be, e.g., larger than the Earth's magnetic field within a near surface region (e.g., layers 112-115) of the pre-polarization coil 105, thus imparting a larger than normal magnetization to the fluid in the near surface region. The pre-polarization current can be shut off in an intentionally abrupt and non-adiabatic manner such that the induced/enhanced magnetization of the fluids, e.g., the fluids in fluid layers 112 and 114, produces a non-zero oscillation about the Earth's static field and thereby produces a detectable NMR free induction decay signal without requiring the application of an alternating transmitted magnetic field excitation pulse B₁. An SNMR signal can be detected on a separate induction coil or coils, such as the SNMR coil 102, or on other magnetic field sensing devices, potentially even using a same coil 105 that produces the pre-polarization field.

The techniques illustrated in FIGS. 2D, 2E, and 2F provide effective means of localizing fluid from different depths below or in the vicinity of the pre-polarization coil 105. The techniques illustrated in FIGS. 2D, 2E, and 2F can optionally be applied in addition to the use of arrays of multiple NMR detection coils with different spatial sensitivity, and/or techniques that alternate direction of the pre-polarization current, as a means to achieve additional depth discrimination.

The techniques illustrated in FIGS. 2D, 2E, and 2F produce one or more switched magnetic gradient fields G in the vicinity of the pre-polarization-induced NMR measurement, in order to enable spatial discrimination in 1, 2 or 3 dimensions. The embodiments illustrated in FIGS. 2D, 2E, and 2F specifically omit the application of excitation pulses B₁. Embodiments that use excitation pulses B₁ are described in connection with FIGS. 2A, 2B, and 2C.

FIG. 2D illustrates an example technique that applies a prepolarization field Bₚ, followed by a applying a gradient field G having a gradient amplitude Gₐₘₚ and a gradient time Gₜᵢₘₑ. An NMR signal is measured after application of the prepolarization field Bₚ and the gradient field G.

Techniques according to FIG. 2D can be used for prepolarization-based phase encoding. The gradient field G can comprise phase cycling gradient pulses immediately following the extinguishing of the pre-polarization field Bₚ, followed by detection of the resulting FID signal, i.e., the illustrated NMR signal. Detection of the resulting FID signal can optionally be performed in two or more phase encoding operations. In one operation (A), phase encoding can be accomplished by changing gradient coil current amplitudes Gₐₘₚ. In another operation (B), phase encoding can be accomplished by changing gradient coil current pulse lengths Gₜᵢₘₑ. Finally, a combined phase encoding can be produced by combining the phase encodings produced according to operation (A) and operation (B).

Techniques according to FIG. 2E can be used for prepolarization-based frequency encoding. The gradient field G can be switched on after extinguishing of the pre-polarization field Bₚ and before and/or during the window for detection of the NMR signal. In this case, fluid at different depths or distances from the gradient coil 105 can produce NMR signals at different frequencies that can be resolved through frequency analysis.

Techniques according to FIG. 2F can be used for prepolarization-based gradient echoes. In FIG. 2F, one or more gradient fields, e.g., the illustrated dephasing gradient and rephasing gradient, can be switched between positive and negative states, e.g., by alternating the direction of current flow through the gradient coil 105, thereby creating gradient echo NMR signals that exhibit frequency encoding and hence can be spatially resolved via frequency analysis.

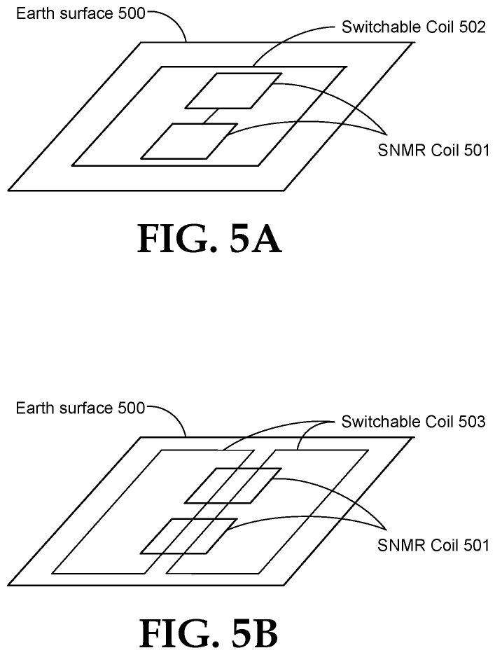

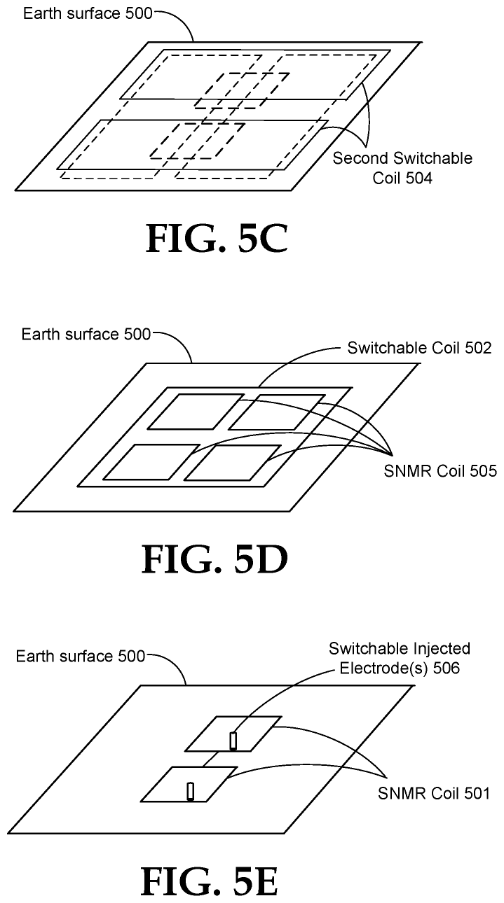

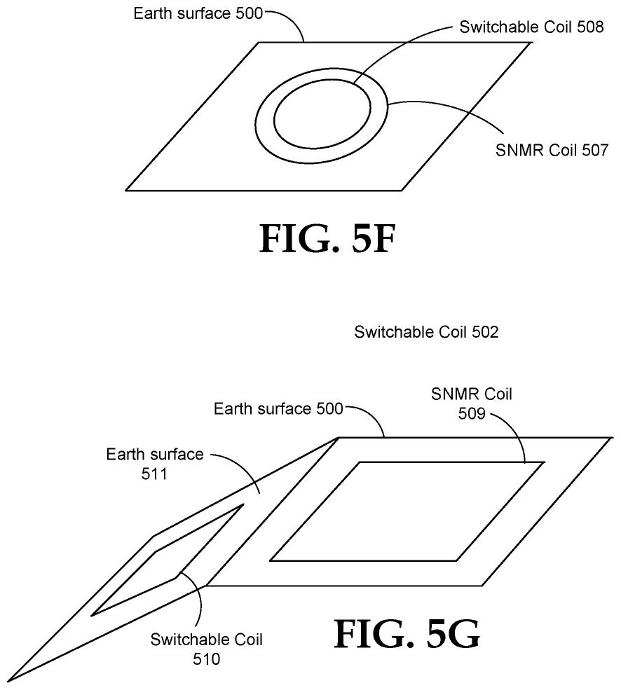

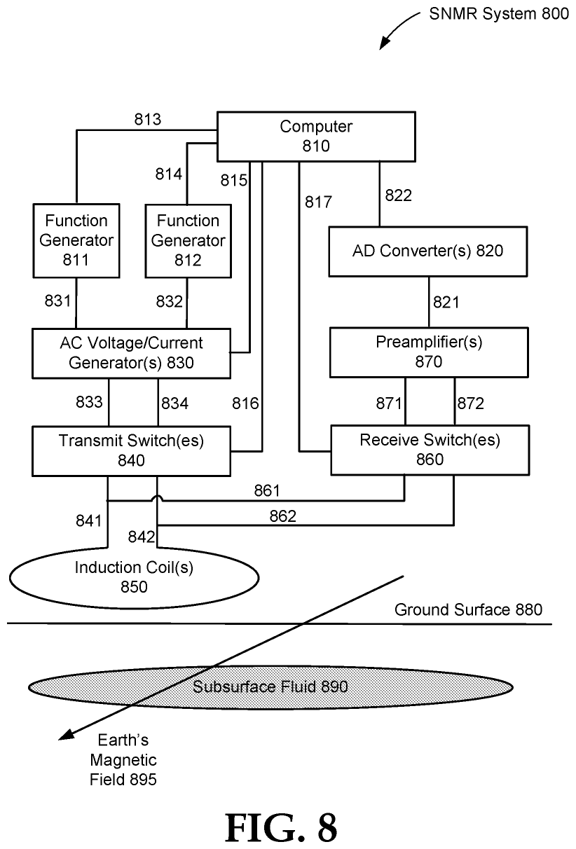

In some embodiments, the techniques illustrated in FIGS. 2D, 2E, and 2F can be carried out using a same switchable coil 105 for both pre-polarization coil and for generating one or more of the switched gradient fields. The detection of NMR signals can be accomplished, e.g., using an SNMR coil 102, which can optionally be configured as one or more figure 8 coils used for NMR detection. In some embodiments, the techniques illustrated in FIGS. 2D, 2E, and 2F can be carried out using two or more gradient coils to generate spatial localization capability in 2 or 3 dimensions. In some embodiments, the technique illustrated in FIG. 2F can apply spin echo refocusing pulses following the pre-polarization generation of the FID signal, to generate spin echoes for detection. Such an approach is useful for example when working in a constant gradient field for frequency encoding. FIG. 5 illustrates various example coil configurations, any of which can be used in connection with the techniques of FIGS. 2A, 2B, and 2C, or in connection with the techniques of FIGS. 2D, 2E, and 2F.

In some embodiments, existing SNMR instruments such as the GMR instrument made by VISTA CLARA INC can be modified to carry out the techniques disclosed herein. The GMR architecture can support switched-field functionality. Specifically, the GMR incorporates an efficient H-bridge architecture to output high current pulses, flexible pulse programing, multi-channel wide-band transmit and receive capability to record frequency and phase-encoded signals, extremely low input noise (<0.3 nV/rt Hz), ultra-fast switching (milliseconds), and auxiliary lines to synchronize measurement timing. These core electronics can be modified and employed as described herein.

As can be understood with reference to FIG. 1, and FIGS. 2A-2F, embodiments of the present disclosure can include an SNMR measurement apparatus comprising, e.g., equipment such as 102 or 105, adapted to apply an NMR response stimulating magnetic field in a sample volume. When the SNMR coil 102 is used to apply the NMR response stimulating magnetic field, then the NMR response stimulating magnetic field can be a magnetic field 103 comprising an excitation pulse. When the switchable coil 105 is used to apply the NMR response stimulating magnetic field, then the NMR response stimulating magnetic field can be a prepolarizing field of magnetic fields 106. The sample volume can be under an Earth surface, or for example within an engineered flow management structure as described above. The NMR response stimulating magnetic field 103 or 106 can stimulate an NMR precession response in a fluid within the sample volume, e.g., in fluid layers 112 and/or 114.

The SNMR measurement apparatus can further comprise equipment 101 and 102 adapted to detect and record an NMR response signal emitted from the sample volume in response to the NMR response stimulating magnetic field 103 or 106. Additionally, the SNMR measurement apparatus can comprise equipment such as 104 and 105 adapted to apply a switched gradient field, e.g. as a field 106 in the sample volume, wherein the switched gradient field 106 is configured to produce a phase, frequency, or slice encoding effect on the NMR response signal, and wherein the phase, frequency, or slice encoding effect on the NMR response signal can be used for spatial localization of the NMR response signal.

In some embodiments, the NMR response stimulating magnetic field can comprise only a prepolarizing magnetic field, as a field 106, without an NMR excitation pulse 103 generated by the SNMR coil 102. The prepolarizing magnetic field 106 can be terminated non-adiabatically according to FIGS. 2D-2F. In some embodiments, the NMR response stimulating magnetic field can comprise an NMR excitation pulse 103 as illustrated in FIGS. 2A-2C.

The SNMR measurement apparatus can optionally further comprise equipment adapted to apply a prepolarizing magnetic field in the sample volume. For example, in FIG. 1, the switchable coil 105 can be adapted to use the switchable coil 105 to apply the prepolarizing magnetic field as a field 106.

In some embodiments, the equipment adapted to apply the NMR response stimulating magnetic field can comprise an SNMR coil 102, the equipment adapted to detect and record the NMR response signal can also comprise the SNMR coil 102, and the equipment adapted to apply the switched gradient field 106 can comprise a switchable gradient field generation element such as switchable coil 105, which can be separate from the SNMR coil 102.

As described further in connection with FIG. 4, the SNMR electronics 101 can comprise a transmitter that includes transmit and receive connections adapted to connect with the SNMR coil 102, a communication connection adapted to communicatively couple the transmitter with a switched field module, e.g., 104. The switched field module 104 can comprise transmit connections adapted to connect with the switchable gradient field generation element, e.g., with switchable coil 105. The SNMR coil 102 and the switchable gradient field generation element 105 can be arrangeable on the Earth surface or the engineered flow management structure. The transmitter 101 can be adapted to transmit the NMR response stimulating magnetic field 103 via the SNMR coil 102. The transmitter 101 can be furthermore adapted to control the switched field module 104 via the communication connection 107, to cause the switched field module 104 to transmit the switched gradient field 106 via the switchable gradient field generation element 105. The transmitter 101 can be furthermore adapted to receive the NMR response signal via the SNMR coil 102. The transmitter 101 can be furthermore adapted to control the switched field module 104 via the communication connection to cause the switched field module 104 to transmit a prepolarization field (also illustrated as 106) via the switchable gradient field generation element 105.

Example SNMR measurement methods according to FIG. 1 and FIGS. 2A-2F can comprise applying an NMR response stimulating magnetic field, e.g., 103 or 106, in a sample volume, wherein the sample volume is under an Earth surface or within an engineered flow management structure, and wherein the NMR response stimulating magnetic field 103 or 106 stimulates an NMR precession response in a fluid within the sample volume; detecting and recording an NMR response signal emitted from the sample volume in response to the NMR response stimulating magnetic field 103 or 106; and applying a switched gradient field 106 in the sample volume, wherein the switched gradient field 106 is configured to produce a phase, frequency, or slice encoding effect on the NMR response signal, and wherein the phase, frequency, or slice encoding effect on the NMR response signal can be used for spatial localization of the NMR response signal. The NMR response stimulating magnetic field can optionally comprise only a prepolarizing magnetic field without an NMR excitation pulse, wherein the prepolarizing magnetic field is terminated non-adiabatically as described in connection with FIGS. 2D-2F. Alternatively, the NMR response stimulating magnetic field can comprise an NMR excitation pulse as described in connection with FIGS. 2A-2C. Furthermore, a prepolarizing magnetic field can optionally be applied in the sample volume.

In an example method, the NMR response stimulating magnetic field can be applied using the SNMR coil 102, wherein the SNMR coil 102 is also used to detect and record the NMR response signal. The switched gradient field can be applied using the switchable coil 105, which can be separate from the SNMR coil 102. In some embodiments, applying the switched gradient field can be performed after applying an NMR response stimulating magnetic field and before detecting and recording the NMR response signal in order to produce the phase encoding effect illustrated in FIG. 2A. In some embodiments, applying the switched gradient field can be performed after applying the NMR response stimulating magnetic field and during detecting and recording the NMR response signal in order to produce the frequency encoding effect, as illustrated in FIG. 2B. In some embodiments, applying the switched gradient field can be performed during applying the NMR response stimulating magnetic field and before detecting and recording the NMR response signal in order to enable slice encoding, as illustrated in FIG. 2C.

SNMR measurement methods disclosed herein can use the Earth's magnetic field as a background magnetic field, and can detect hydrogen spins associated with fluids. In some embodiments, SNMR measurements can comprise a series of NMR measurements, and wherein in a gradient amplitude or duration is varied between NMR measurements of the series of NMR measurements. Values of gradient fields can be calculated or approximated resulting gradient field values can be used to localize and quantify sources of NMR signals within the one or more NMR measurements. The calculating use, e.g., linear equations. Values of a prepolarizing field can optionally also be calculated or approximated to localize and quantify sources of NMR signals within the one or more NMR measurements. In some embodiments, a series of the one or more NMR measurements can be used to establish a spatial distribution of a property, wherein the property comprises at least one of fluid quantity, NMR relaxation time, mobile fluid content, bound fluid content, or permeability.

In some embodiments, imposing a magnetic gradient can comprise imposing magnetic gradients in multiple directions. The magnetic gradients in multiple directions can be imposed for depth imaging and/or for lateral imaging, as well as for imaging in 2D or 3D.

Anticipated Benefits

The storage and movement of fluids through the shallow subsurface, known as Earth's critical zone, has direct impacts on factors of society and the natural world ranging from human health to ecosystem health, contaminant remediation, groundwater availability, food production, civil engineering, and climate change. By bringing to market a non-invasive technology that can be used to more efficiently and accurately image groundwater and fluid saturated soils, the use of technologies described herein can benefit public and private organizations operating in these disciplines.

Some of the groups that can benefit from this technology are governments, utilities, and private companies charged with protecting groundwater from existing contamination liabilities and future contamination risks. These organizations commonly face imaging challenges including identification of leaking fluids below waste liners, delineation of high permeability flow paths, and mapping of static and perched water tables. These institutions will benefit from the reduced ambiguity and lower total costs afforded by this innovation. Specific groups in the U.S. Federal government that would benefit from this technology include the Department of Energy and Department of Defense, who are responsible for numerous groundwater contamination sites, as well as other agencies responsible for groundwater management and protection including the Environmental Protection Agency and the Department of Interior.

The technologies described herein are also motivated by the growing societal need to characterize and image thaw in Earth's cryosphere. Changes in permafrost and seasonally frozen ground have accelerated over the past decades and have important implications for arctic ecosystems, carbon release, and artic infrastructure and economic development. Research organizations and engineering firms struggle with limited data and methods available to map thawing ground. This technology would enable more accurate imaging of unfrozen water in the shallow subsurface resulting in more thorough modeling and prediction to inform policy, adaptation, and engineering strategies.

Shallow groundwater plays a critical role across many other realms of society. In geotechnical engineering, shallow groundwater influences dewatering designs, soil stability, and storm water infiltration. Embodiments of this disclosure can allow geotechnical engineers to more efficiently and accurately map variations in groundwater storage, minimizing risk and leading to better, safer engineering designs. Agricultural engineering and farming depend critically upon knowledge of soil water distribution and irrigation strategies informed by subsurface imaging can improve water use in water-stressed areas. The ability to image shallow groundwater is also key to understanding biogeochemical reactions that affect not only contaminant mobilization but also nutrient cycling and global atmospheric inputs.

### Gradient Encoding

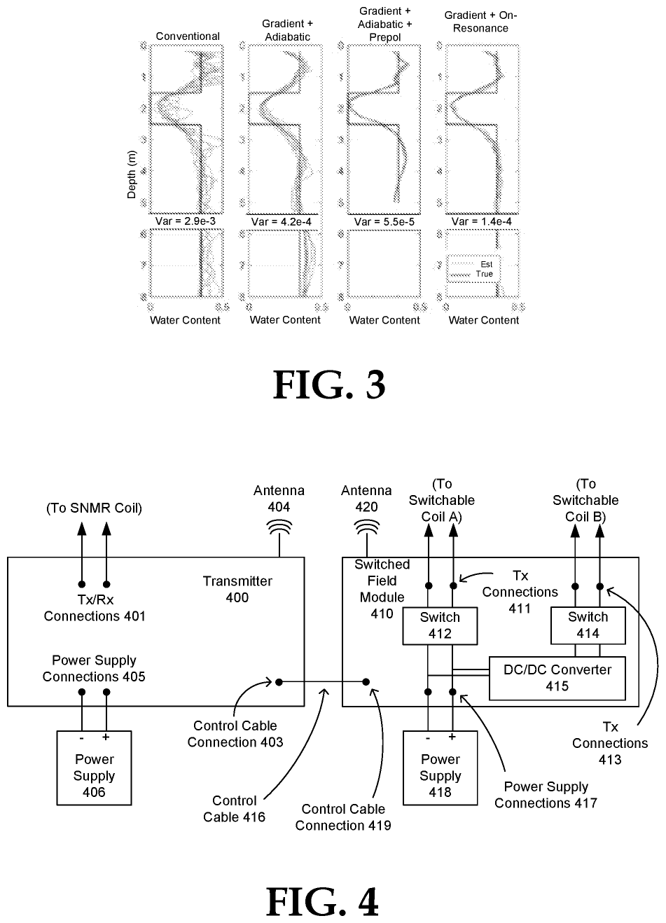

FIG. 3 illustrates an example comparison of acquisition methods, in accordance with various aspects and embodiments of the subject disclosure. FIG. 3 includes, at left, example simulated NMR data collected using a conventional SNMR method, without the use of a gradient G. Next, FIG. 3 illustrates a simulation of example data collected using a gradient G and an adiabatic excitation pulse B₁. Next, FIG. 3 illustrates example simulated NMR data collected using a gradient G, an adiabatic excitation pulse B₁, and a prepolarization pulse Bₚ. Finally, FIG. 3 illustrates example simulated NMR data collected using a gradient G and an on-resonance excitation pulse B₁.

Gradient-encoding methods according to this disclosure can use phase and/or frequency encoding. The mathematics of phase and frequency encoding are largely the same, and so this disclosure focuses on the phase-encoding approach with the understanding that similar techniques can be applied for frequency encoding. Phase encoding includes calculation of coil fields, effective gradient maps, Bloch-equation excitation, and gradient-phase accumulation. Furthermore, inversion schemes can allow depth resolution without the use of changing excitation pulses.

Phase encoding and frequency encoding methods are functionally almost equivalent in terms of their ability to spatially resolve signals. The primary difference is the way in which the data are acquired: for phase encoding the full-time domain FID signals are sampled at discrete values of the gradient moment. For frequency encoding the instantaneous amplitude of the FID signal is measured over a continuous range of gradient moments while the frequency encoding gradient is active. For the case where FID signals are long relative to the gradient encoding time, the data produced by the methods contains the same Fourier information, but the phase encoding method also contains FID time-domain information. In phase encoding, sampling the time-domain behavior of the signal is useful for assessing hydraulic conductivity.

Switched coils 105 can be used to incorporate prepolarizing switched fields Bₚ in some embodiments. Prepolarizing switched fields Bₚ can also be simulated through Bloch model simulations. Prepolarization increases gradient-encoding performance, especially for shallow targets in the upper 5 m of the Earth's subsurface.

Including on-resonance pulses with gradient-encoding can further improve results. FIG. 3 shows a comparison between alternative methodologies. For the selected example, the Earth model is a layer of shallow water. Noise is added to an ensemble of 10 simulations and the resolution and variance of the inversion is assessed. The switched field methods, i.e., those using a gradient G, are confirmed to improve resolution and variance in comparison to the conventional approach at left. Alternatively, adiabatic pulses with gradient-encoding can be used instead of, or in addition to the on-resonance pulses.

In addition to phase-encoding, slice selective excitation can improve resolution. A consideration that applies both to slice-selection and phase-encoding is matching or tuning the gradient field G with the excitation pulse B₁ to enhance sensitivity. Gradient and excitation field parameters can be matched to increase sensitivity. For example, in the case of slice-selective excitation, the spatial slice defined by the gradient field can be coincident with the slice in which excitation fields produce a 90° tip angle. Similarly, in the case of gradient on-resonance experiments, many combinations of gradient and excitation fields provide poor sensitivity (e.g. a large gradient moment and a small excitation pulse moment yield no coherent signal). In order to increase the efficiency of gradient on-resonance measurements, gradient and excitation pairs that will contribute most to sensitivity and resolution should be selected. To this aim, algorithms can pair gradient and excitation pulses.

### Switched-Field SNMR Hardware

FIG. 4 illustrates example hardware that can be used to implement SNMR electronics and switched gradient and prepolarization electronics, in accordance with various aspects and embodiments of the subject disclosure. FIG. 4 includes a transmitter 400 that can implement a component of the SNMR electronics 101 introduced in FIG. 1, and a switched field module 410 that can implement a component of the switched gradient and prepolarization electronics 104 introduced in FIG. 1.

The example transmitter 400 includes transmit/receive (Tx/Rx) connections 401 adapted to connect to an SNMR coil, such as SNMR coil 102. The example transmitter 400 further includes power supply connections 405 adapted to connect to a power supply 406, and either or both of a control cable connection 403 adapted to connect to a control cable 416, or an antenna 404 adapted to wirelessly communicate with the switched field module 410.

The example switched field module 410 includes Tx connections 411 adapted to connect to an example switchable coil A, such as switchable coil 105. The Tx connections 411 can be connected to power supply connections 417 via a switch 412. The power supply connections 417 can be furthermore adapted to connect to a power supply 418. As an optional additional feature not illustrated in FIG. 1, the switched field module 410 can furthermore comprise Tx connections 413 adapted to connect to an additional switchable coil B. The Tx connections 413 can be connected to power supply connections 417 via a switch 414 and a DC/DC converter 415, as shown. The example switched field module 410 also includes either or both of a control cable connection 419 adapted to connect to the control cable 416, or an antenna 420 adapted to wirelessly communicate with the transmitter 400.

FIG. 4 illustrates an example system comprising a switched field module 410 controlled via wired or wireless synchronization with the transmitter 400. In some embodiments, the switched field module 410 can include, e.g., a single-channel switched field generator using H-bridge inverters and control printed circuit boards (PCBs), or a multi-channel switched field generator using insulated-gate bipolar transistor (IGBT) devices and control boards. The switched field generator can be controlled by the transmitter 400 through a control cable 416 or by wireless global positioning system (GPS) synchronized data acquisition (DAQ) boards. The final number and arrangement of DC field generators and DC power supplies can be adapted as needed to suit the needs of particular embodiments.

In an example embodiment, a switched-field module 410 can be connected to an interface control cable 416 and a 48V battery bank 418; and cables can deliver the outputs of the module 410 to the gradient or prepolarization coils, e.g., to switchable coils A and B. The switched-field module coils A and B can comprise inductances ranging from 1 mH to 10 mH and resistances ranging from 0.4 to 2 ohm. The circuit design of the switched-field module 410 can allow fast linear shutoff times with a slope of approximately L/R (on the order of 1-10 ms). Direct monitoring of the coil A and B currents through a data acquisition card can allow for precise assessment of ramp up and shutoff behavior and can also provide capabilities for over-current fault protection.

Prepolarization outputs of the switched field module 410 can be configured to receive DC power from a power supply 418 (e.g., a 12-72 volt power supply). Gradient outputs of the switched field module 410 can be configured to draw from either batteries or a boosted capacitor bank, e.g., a 540 volt (V) capacitor bank. The high voltage outputs can optionally also be used to drive a second transmitting coil (switchable coil B) in parallel, e.g., for quadrature excitation.

The transmitter 400 can include, e.g., features of a GMR type transmitter made by VISTA CLARA INC. The transmitter 400 can further include features aimed at simplifying switched field methods that make use of the switched field module 410, while also delivering enhanced performance, streamlined manufacturing, and expanded market access. Commercial off-the-shelf assemblies for data acquisition and alternating current (AC) power generation can be expensive and bulky components which stymie reductions in size, cost, and weight. A transmitter 400 can optionally integrate low-cost computing and power generation components, described below. Features of the transmitter 400 can include, e.g., a flexible, powerful, and low-cost control of the switched-field module 410, to enable generating multiple gradient and pre-polarization fields from a range of power supplies, wherein the gradient and pre-polarization fields are synchronized with SNMR measurements performed by the transmitter 400. A transmitter 400 architecture can incorporate several innovations to simplify the integration of switched field acquisition, while reducing physical size, cost and complexity. These include (i) a custom FPGA-based data acquisition board to simplify control, enable modularization, expand capabilities, and reduce manufacturing costs, (ii) a simpler, smaller and lighter H-bridge power conversion unit; and (iii) high-voltage (4 kV-6 kV) solid-state receive switches to improve the switching speed and reduce cost and complexity.

In some embodiments, the transmitter 400 can include an FPGA-based data acquisition board. In other embodiments, the transmitter 400 can include National Instruments data acquisition devices. FPGA-based data acquisition boards are usefully included in some embodiments to decrease DAQ materials cost. Furthermore, FPGA-based data acquisition boards can allow simplified support of the switched field requirements for synchronized pulse control on multiple IGBTs and on multiple modules.

The GMR transmitter is intended to produce outputs in the range of 500 Hz-5000 kHz with peak currents of 600 A and peak voltages of 8000 V. In some embodiments, such a transmitting architecture can be modified to produce DC fields with similar power limits and with the capability to quickly shut off fields through high inductance coils. The system can be configured to allow bus voltages to be provided by the GMR DC/DC converter (up to 540V) or from external car batteries (12-72V). Control and monitoring auxiliary connectors can be designed and integrated so the module 410 can be controlled and monitored from a main GMR unit 400. In some embodiments, the DC switched-field electronics 410 can optionally be integrated into the housing for a transmitter 400, e.g., into a GMR flex type transmitter with shock mounting for field use.

Example hardware and software of the switched gradient and prepolarization electronics 104 can generate and control large amplitude direct current DC switched fields with fast shutoff. Hardware for DC-switched fields can be capable of performing surface-NMR methods with added control and synchronization of switched fields. Example switched field modules such as 410 can generate, e.g., currents up to 600 Amps, with supply voltage from a 12-72V battery bank and/or high-voltage DC/DC converter charged capacitors (540V).

Shutoff times through high inductance coils are on the order of 1-10 milliseconds. In some embodiments, circuitry design of switched field modules can be based on a robust IGBT H-bridge architecture. The control of the H-bridge can be further improved through an IGBT controller that can reduce the size and complexity of the design.

Furthermore, embodiments can comprise easy-to-use commercial acquisition software for switched-field survey planning, data acquisition, processing, and interpretation. The software can include a software-firmware interface for the acquisition of multi-mode SNMR data, including control and monitoring of pre-polarization and gradient fields, NMR data integrity, and system status. The software can furthermore include user-facing software tools to assist in selecting survey parameters, coil geometries, pulse sequences, and switched field parameters to achieve imaging targets or survey objectives. The software can include user-facing processing and interpretation software to enable optimized inversion, uncertainty analysis, and interpretation of surface-NMR data acquired with switched-field or conventional surface-NMR methods.

The illustrated hardware can be adapted to generate certain DC field strengths and power consumption to successfully image at particular depths of investigation. For prepolarization fields, the field strength at a given depth can be a factor of N stronger than Earth's field (0.5G) to produce a factor of —N increase in the signal amplitude. This translates to very high values of amp-turns for coils, which are practical for loops up to ˜10 m diameter (e.g. a 5 m loop requires 2000 amp-turns for a factor of 3 increase at 3 m depth). Gradient coils, however, can be restricted to not exceed the magnitude of Earth's field to avoid erratic spin dynamics. This means power requirements for gradient coils are much lower than equivalently sized prepolarization coils, but gradient coils can be much larger. A 30 m gradient coil can use around a few hundred amp-turns for phase encoding.

Switching times for the DC fields can be on the order of several milliseconds without significant degradation of results. For gradient fields, the gradients can be on for tens of milliseconds to induce phase shifts where the gradient is weak. Therefore, relaxation that occurs during the gradient on time will be more significant than that that occurs during a few milliseconds (ms) of switching. For prepolarization coils, a fast shutoff is preferable as T₁ relaxation will occur only once the prepolarization field is shut off. However, for high inductance prepolarization coils, it is practical to achieve shutoffs of a few milliseconds, so detection of signals with very short T₁ will be limited. It remains important to have a short dead-time between the excitation pulse and the received signal.

Certain hardware architectures can be best suited to achieve the necessary power and switching requirements. Hardware can employ circuit architectures that can switch several hundred amps with shutoff times of a few millisecond for high inductance coils. Hardware can comprise an existing GMR system's IGBT transmitting circuitry. Utilizing this well-understood and robust circuitry minimizes engineering risk and will also minimize production costs. The bus voltage for the DC switched fields can be provided by the GMR high-voltage bus capacitors (up to 540V) or from batteries (12-72V) depending on the needs of the experiment.

### Coil Geometry Variations

FIGS. 5A, 5B, 5C, 5D, 5E, 5F, and 5G illustrate various example coil configurations, in accordance with various aspects and embodiments of the subject disclosure. FIGS. 5A, 5B, 5C, 5D, 5E, 5F, and 5G include example coil arrangements on an Earth surface 500.

FIG. 5A can be used for depth encoding methods, in which a gradient field varies as a function of subsurface depth. In FIG. 5A, a figure-8 type SNMR coil 501 is positioned inside a square switchable coil 502.

FIG. 5B can be used for lateral encoding methods, in which a gradient field varies as a function of lateral position. In FIG. 5B, the figure-8 type SNMR coil 501 is positioned inside a larger figure-8 type switchable coil 503.

FIG. 5C can be used for three dimensional (3D) encoding methods, in which a gradient field varies as a function of lateral position and depth. FIG. 5C can use the figure-8 type SNMR coil 501 positioned inside a larger figure-8 type switchable coil 503, as shown in FIG. 5B, which are depicted in dashed lines in FIG. 5C. FIG. 5C further includes a second figure-8 type switchable coil 504, which is rotated 90 degrees with respect to the switchable coil 503.

FIG. 5D can be used for multiloop quadrature NMR and noise cancelation methods. In FIG. 5D, a four-loop type SNMR coil 505 is positioned inside a square switchable coil 502.

FIG. 5E can be used when injectable electrode(s) are desired in addition to or instead of a switchable coil. In the illustrated embodiment, switchable injected electrode(s) 506 are inserted into the Earth surface 500. The switchable injected electrode(s) 506 are placed in the centers of the loops of the SNMR coil 501, however, other arrangements are also feasible. Switchable coils such as 502, 503, and 504 and/or switchable injected electrode(s) 506 may be referred to either individually or collectively herein as “switchable gradient field generation element(s)”.

FIG. 5F illustrates another example coil configuration wherein a switchable coil and a SNMR coil are elliptical in shape, and wherein the SNMR coil is smaller than the switchable coil, in accordance with various aspects and embodiments of the subject disclosure. In FIG. 5F, a circular or otherwise elliptical SNMR coil 507 surrounds a circular or otherwise elliptical switchable coil 508. The SNMR coil 507 has a larger diameter than the switchable coil 508, and the switchable coil 508 is entirely inside the SNMR coil 507. It will be appreciated that the SNMR coil 507 and the switchable coil 508 can be of any shapes and sizes. The SNMR coil 507 can be larger than the switchable coil 508, smaller than the switchable coil 508, or of equal size as the switchable coil 508. Furthermore, the switchable coil 508 can be positioned inside the SNMR coil 507, or surrounding the SNMR coil 507, or partially overlapping the SNMR coil 507.

FIG. 5G illustrates another example coil configuration wherein a switchable coil and a SNMR coil are not coplanar, in accordance with various aspects and embodiments of the subject disclosure. In FIG. 5G, an SNMR coil 509 is positioned on the Earth surface 500, and a non-coplanar switchable coil 510 is placed on an Earth surface 511. In the illustrated embodiment, the switchable coil 510 is positioned adjacent to the SNMR coil 509 and the switchable coil 510 is at an angle with respect to the SNMR coil 509. The angle can be, e.g., any angle from 1-90 degrees. Furthermore, in other non-coplanar embodiments, the switchable coil 510 can be positioned above or below the SNMR coil 509.

FIG. 1 and FIGS. 5A, 5B, 5C, 5D, 5E, 5F, and 5G provide some example coil geometry variations that can be deployed in different embodiments and for different purposes. It will be appreciated that other coil geometries are also possible, and this disclosure is not limited to any particular coil geometry.

The coil geometries illustrated in 5A, 5B, 5C, 5D, 5E, 5F, and 5G enable depth encoding, lateral encoding, 2D/3D resolution, quadrature detection, and proximal loop noise cancellation. The relative sizes and geometries of the switchable gradient coils, prepolarization coils (if separate from the switchable gradient coils), and SNMR coils is an important parameter controlling measurement sensitivity. Beginning with the basic case of one dimensional (1D) imaging, coil geometries can be determined for resolving targets at particular depths, given variable geomagnetic field conditions. Secondary gradient coils, such as second switchable coil 504, can optionally be used to improve the linearity of a gradient field with depth. Secondary gradient coils can comprise concentric gradient coils as shown in FIG. 5C.

Switched fields may also be used to create lateral sensitivity for 2D or 3D imaging. In FIG. 5A, a square switchable gradient coil 502 creates a gradient oriented with depth enabling depth imaging. In FIG. 5B, a figure-8 switchable coil 503 creates a gradient oriented along the axis of the figure-8 so that lateral position can be encoded with the gradient. Taking this concept one step further, in FIG. 5C, two figure-8 switchable coils 503 and 504 enable separate encoding in the x and y direction supporting 3D imaging.

The concept of multiple gradient coils can also be extended to multiple transmit and receive coils. Pairs of coils can be combined, as illustrated in FIG. 5D, to create quadrature detectors and improve spatial encoding and signal-to-noise ratios. With FPGA control electronics, embodiments can transmit and receive on quadrature coil pairs (e.g. perpendicular figure-8 coils). Multi-coil receive arrays also provide opportunities for noise cancellation using coil pairs that are both sensitive to NMR signals.

Gradient polarity and phase-cycling is an NMR method in which data pairs are acquired with opposite polarity or phase. Because NMR signals have phase coherent components, data pairs with opposite phase or polarity can be added or subtracted to isolate these signal components. In addition to cycling the phase of excitation pulses, the direction of frequency sweeps or sign of frequency offsets can be cycled to produce similar isolation. Cycling the polarity of the gradient field can provide improved sensitivity and resilience against artifacts (e.g. from magnetic geology).

Another consideration is the relative sizes of the switched gradient coils and main transmitting SNMR coils. In some embodiments, the gradient coil can be substantially larger, e.g., 50% larger or more, than main coil. This geometry ensures that the main excitation coil has low sensitivity near the edge of the gradient coil where there is high heterogeneity in the gradient field. In some other embodiments, the size of gradient coil can be equal or even smaller than that of the excitation coil, e.g., as illustrated in FIG. 5F. Furthermore, embodiments can configure the gradient coil to produce fields that are parallel or antiparallel with Earth's field. This means that for a high magnetic inclination, circular or square loops can be most effective, but for low magnetic inclination, figure-8 coils can be most effective.

Two additional example loop geometries can include, first, a small geometry wherein a switched gradient coil comprises a 10 m circle with 90 Amp-turns, and a SNMR coil comprises a 6 m circle with 5 turns. Second, in an intermediate geometry, a switched gradient coil can comprise a 20 m circle with 180 Amp-turns, and a SNMR coil can comprise a 12 m circle with 5 turns. In an example deployment, the intermediate geometry can be deployed, e.g., to image five subsurface Earth layers, with two 1-m water layers at depths of 2 m and 4.5 m; each of the layers having different values of T2*.

In another embodiment, example hardware can include a 5 m switchable coil coincident with a 5 m SNMR coil. The switchable coil can have, e.g., 14 turns and a high inductance of approximately 5 mH. For prepolarization, the switchable coil can be energized using the switched-field module and a 36V bus voltage from car batteries, resulting in a polarization current of ˜50 A. The ring-up time can be less than 5 ms and the turn off time can be less than 2 ms.

Embodiments can use standard 10 AWG cable, modest current, and a relatively short polarization pulse (500 ms). Increasing the polarization current by a factor of three (achieved with larger gauge wire or larger bus voltage) can result in up to a 10-fold increase in signal amplitude compared to the measurement without prepolarization.

In another example of gradient-based imaging with surface NMR hardware, a configuration can include a switchable coil of 17 m and a SNMR coil of 13 m centered in the switchable coil. Data can be acquired using a gradient-adiabatic framework with seven different values for the gradient moment. The gradient current waveforms can be directly sampled by the switched-field module. The current can be measured directly to accurately determine the gradient moment given the actual ring up and turn off shapes. Wideband FID data (after noise cancellation) can result from the seven different gradient moments. The gradient-encoding has a strong influence on the recorded signals, primarily observed as a decrease in the initial amplitude of the signals.

### Switched-Field SNMR Software

Software to control the disclosed switched field measurement techniques can be adapted for efficient data collection as well as planning processing and interpretation software for reducing collected data into image products that quantify fluid content and aquifer properties of interest to the end user. Example software can include: a software-firmware interface for the acquisition of multi-mode surface NMR data, including control and monitoring of pre-polarization and gradient fields, NMR data integrity, and system status; user-facing software tools to assist in selecting survey parameters, coil geometries, pulse sequences, and switched field parameters to achieve particular imaging targets or survey objectives; and user-facing processing and interpretation software to enable optimized inversion, uncertainty analysis, and interpretation of surface-NMR data acquired with switched-field or conventional surface-NMR methods.

Users cannot be expected to determine optimal survey variables such as coil geometries, gradient amplitude, or pulse modulation. A typical user wants to spend their time in the field getting useful data, not experimenting with a spectrum of acquisition parameters. Embodiments can therefore provide semi-automated survey parameter determinations. This can be implemented via logical algorithms that take as input particular aspects of the survey constraints and imaging target (e.g. target resolution, target depth, geomagnetic field inclination, mobile or bound water). These logical algorithms can provide as output the relevant variable for the type of survey being conducted.

In an embodiment, data acquisition software can be augmented with modules for generation and control of pre-polarization and gradient circuits. Control signals can be realized as analog output signals on designated hardware channels and can be synchronized with existing NMR excitation waveforms. An analog input channel can be programmed to measure the current through the switched field for safety monitoring and for use in data processing. Example software that executes during execution of a gradient-encoding measurement can provide a display showing receive channels, the AC current on the SNMR main coil, and the DC current on the gradient coil. Software modules can be configured to support adiabatic pulses with prepolarization as well as to support gradient-encoded imaging with adiabatic pulses and gradient-encoded imaging with on-resonance pules.

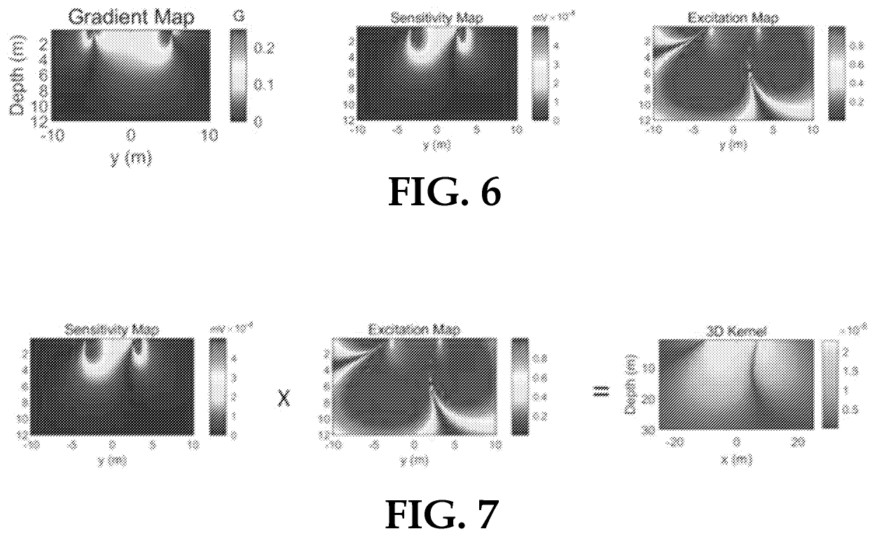

FIG. 6 illustrates components of surface NMR kernel for a gradient-adiabatic experiment, in accordance with various aspects and embodiments of the subject disclosure. FIG. 6 includes (a) an example gradient map created by calculating gradient fields for a 10-m surface soil, (b) an example sensitivity map created by calculating excitation fields for a 6-m surface coil, and (c) an example excitation map created by Bloch equation solutions for the particular excitation pulse.

Embodiments of this disclosure can do more than analyze NMR data by Fourier transform of acquired data. Embodiments can compile complete forward models that include all coil fields, excitation processes, and gradient-encoding physics. These forward models can then be used to construct mathematical kernels that are used to retrieve spatial information by inversion. A simulation framework can incorporate any combination of a gradient, detection and prepolarization loops. For 3D numerical modeling of the surface NMR kernel, a generic 3D simulation can be densely discretized and built automatically based on the dimension of gradient, excitation/detection and prepolarization loops, and can ensure dense sampling in all three dimensions. These simulations can include the following modules, which can be configured to integrate into a single simulation: Gradient Coil Fields; Main Coil Fields; Prepolarization Coil Fields; Field Projections onto an arbitrary geomagnetic field; Bloch equation solutions for on-resonance, off-resonance, and adiabatic excitations; Bloch equation solutions for prepolarization with arbitrary shut-off; Quantitative coil voltages as a function of NMR magnetization.

Adiabatic phase encoding simulation is a form of switched-field measurement that can be simulated. In adiabatic phase encoding simulation, an adiabatic pulse is used for excitation and is followed by phase encoding. As for all experiments, this can involve forming a modelling that simulates fields for both the gradient and detection coils. The dimensions of a gradient loop can be selected such that it produces fields that are a fraction of geomagnetic field and has a monotonic shape below the detection loop.

It is primarily the component of the gradient field that is parallel to Earth's field which can be calculated to determine the phase shift (the gradient field can also be small relative to Earth's field). As a next step, embodiments can compute detection coil fields and their transverse components to the Earth field. These computations form the basis for sensitivity mapping as shown for example in the middle of FIG. 6 for a 6 m surface coil. For adiabatic excitation, embodiments can use complete Bloch model simulations to model the adiabatic spin excitation dynamics. The Bloch simulations can be used to construct a look up table from which the excited magnetization is determined based on the value of the transverse excitation field at any depth. The excited transverse magnetization forms the excitation map on the right side of FIG. 6.

FIG. 7 illustrates calculation of the 3D Kernel without phase encoding as the product of a sensitivity map and an excitation map, in accordance with various aspects and embodiments of the subject disclosure. As shown in FIG. 7, excitation and sensitivity maps allow calculation of a 3D surface NMR kernel.

Embodiments can include source code libraries that include 3D forward modelling of (i) AC and DC fields, (ii) Bloch equation magnetization resulting from prepolarization, adiabatic excitation, on-resonance excitation, or slice-selective excitation (iii) gradient-based phase accumulation (iv) and contamination from cultural noise and magnetic geology. These libraries can be generalized and expanded upon to provide forward modeling algorithms while also providing necessary acceleration to their computational speed.

Calculations can be accelerated by vectorizing all matrix calculations, incorporating the use of lookup tables for Bloch equation solutions, and parallel computation of 3D gradient, prepolarization and on-resonance excitation fields. Support of multi-coil arrays can be added by allowing an arbitrary number of coils with transmitting gradient, prepolarization or receive function. Bloch equation simulation of refocusing pules can be included to support use of spin echo measurements. Non-random structured noise and magnetic susceptibility variations will be added to assess noise mitigation routines and resilience in magnetic geology. Kernel calculations can be expanded to support 2D and 3D imaging datasets with lateral sensitivity resulting from multiple transmit coils, receive coils, or lateral gradient coils.

Generalized forward modeling algorithms and resulting kernels can provide a foundation for a comprehensive data processing and inversion workflow that can include quantification of inversion uncertainty. In a complete simulation, embodiments can forward model an arbitrary switched-field experiment and assess the ability to resolve particular groundwater features by inverting the synthetic data.

Some embodiments can calculate or approximate values of gradient fields over the Earth subsurface and use resulting gradient field values to localize and quantify sources of NMR signals within the one or more NMR measurements. The calculating can use linear equations. Some embodiments can calculate or approximate values of a prepolarizing field to localize and quantify sources of NMR signals within the one or more NMR measurements.

### Example SNMR System

FIG. 8 illustrates aspects of an example SNMR system, in accordance with various aspects and embodiments of the subject disclosure. The example SNMR system 800 includes a computer 810, function generators 811, 812, AC voltage/current generator(s) 830, transmit switch(es) 840, induction coil(s) 850, receive switch(es) 860, preamplifier(s) 870, and Analog to Digital (AD) converter(s) 820. The induction coil(s) 850 are illustrated over a ground surface 880. A subsurface fluid 890 is illustrated beneath the ground surface 880. Earth's magnetic field 895 exists over and under the ground surface 880 and within the subsurface fluid 890.

In FIG. 8, the computer 810 is coupled to function generators 811, 812 by connections 813 and 814, respectively. The computer 810 is also coupled to AC voltage/current generator(s) 830 by connection 815, to transmit switch(es) 840 by connection 816, to receive switch(es) 860 by connection 817, and to AD converter(s) 820 by connection 822. Furthermore, function generators 811, 812 are coupled to AC voltage/current generator(s) 830 by connections 831 and 832, respectively. AC voltage/current generator(s) 830 are coupled to transmit switch(es) 840 by connections 833 and 834. Transmit switch(es) 840 are coupled to both ends of the induction coil(s) 841 and 842. The ends of the induction coil(s) 841 and 842 are coupled to receive switch(es) 860 by connections 861 and 862, respectively. Receive switch(es) 860 are coupled to preamplifier(s) 870 by connections 871 and 872. Preamplifier(s) 870 are coupled to AD converter(s) 820 by connection 821. AD converter(s) 820 are coupled to AD converter(s) 820 by connection 821.

In general, with regard to FIG. 8, the SNMR system 800 may be configured to produce electrical current pulse sequences on the induction coils 850. Each electrical current pulse sequence may comprise one or more oscillating electrical current pulses. When a pulse sequence comprises more than one pulse, the pulses may be separated by a pulse separation time. Also, pulse sequences may be separated by a pulse sequence separation time.

The computer 810 may be configured to produce a pulse by selecting a pulse phase and activating the AC voltage/current generator(s) 830. The computer 810 may be configured to select a pulse phase for example by activating a function generator 811 or 812 corresponding to a desired pulse phase, so that the selected function generator 811 or 812 provides an input pulse phase to the AC voltage/current generator(s) 830, which is then amplified by the AC voltage/current generator(s) 830 to produce a corresponding pulse on the induction coil(s) 850. The computer 810 may also optionally be configured to close one or more transmit switch(es) 840 when activating the AC voltage/current generator(s) 830 and open the transmit switch(es) 840 after activating the AC voltage/current generator(s) 830.

The computer 810 may be configured to produce a pulse sequence by producing a first pulse, then if additional pulses are included in the sequence, waiting for a predetermined pulse separation time, and then producing a next pulse, and repeating until the pulse sequence is complete. The computer 810 may be configured to produce two or more pulse sequences by producing a first pulse sequence, then waiting for a predetermined pulse sequence separation time, then producing a next pulse sequence, and repeating until a desired number of pulse sequences are complete.

The SNMR system 800 may also be configured to receive and record NMR signal data received via the induction coil(s) 850. The SNMR system 800 may be configured to receive and record NMR signal data after one or more pulses within a pulse sequence, and/or after completion of a pulse sequence. In some embodiments, the computer 810 may be configured to close the receive switch(es) 860 after a pulse. The preamplifier(s) 870 amplify desired and undesired signals received via induction coil(s) 850. The AD converter(s) 820 convert the received and amplified signals to digital NMR signal data, e.g. by sampling received signals at a desired sampling rate, and the computer 810 or other device equipped with storage media may be configured to store the digital NMR signal data.

In some embodiments, the computer 810 may be configured to process detected NMR signal data, e.g., to combine NMR signal data received and recorded after one or more pulses within a pulse sequence, and/or received and recorded after completion of pulse sequences, in such a way that preserves desired NMR signal data and cancels undesired NMR signal data. It will be appreciated that while the computer 810 may be configured to perform SNMR processing, in some embodiments SNMR acquisition and SNMR processing may be performed separately, e.g., by first performing SNMR acquisition with a SNMR system 800, then processing acquired SNMR data at a later time and/or with a different computing device.

In some embodiments, computer 810 may be programmed with software that controls the generation of pulse sequences and the acquisition of data. A set of data acquisition devices may comprise devices configured generate the control signals for the pulse sequences, such as function generators 811, 812, and AD converter(s) 820 that receive, convert and/or record SNMR signals. The AC voltage/current generator(s) 830 may be configured to generate one or more current pulses in the induction coil(s) 850 in a transmit mode, to induce a coherent precession of NMR spins in the subsurface fluid 890. Optional transmit switch(es) 840 may be configured to isolate transmitter noise from the receive circuitry during a receive mode. Induction coil(s) 850 may be arranged on or above the surface of the Earth 880, and may be configured to cause a coherent precession of spins in the subsurface fluid 890 in the Earth's magnetic field 895 and also to detect the NMR magnetic fields generated by the coherent precession of spins in the subsurface fluid 895. Optional receive switch(es) 860 may be configured to isolate the receive preamplifier(s) 870 from the potentially large voltage on the induction coil(s) 850 during transmit mode. Optional preamplifier(s) 870 may be configured to amplify the detected NMR signals prior to digitization by the AD converter(s) 820. The optional transmit switch(es) 840 and receive switch(es) 860 may comprise active devices such as relays, and/or passive devices such as diodes. Optional tuning capacitors, not shown in FIG. 8, may be used in the transmit mode to increase the transmitted current in the induction coil(s) 850, and/or in receive mode to increase the amplitude of the NMR signal voltage across the terminals of the induction coil(s) 850.

In some embodiments, induction coil(s) 850 may comprise an array of coils comprising one or more transmit coils, one or more receive coils, and/or one or more combination transmit and receive coils. For example, induction coil(s) 850 may comprise one transmit coil and multiple receive coils. Induction coil(s) 850 may comprise one combination transmit and receive coil, and multiple receive coils. Induction coil(s) 850 may comprise multiple combination transmit and receive coils. These and other multicoil arrangements may be configured in some embodiments as will be appreciated. Multicoil arrangements are useful for localization of subsurface fluids 890, as described for example in U.S. Pat. No. 7,466,128, which is incorporated by reference.

Any combination of hardware and software that enables the acquisition and processing of NMR signals from subsurface liquids in the Earth's magnetic field is suitable to implement embodiments of this disclosure. An architecture to implement the disclosed methods could comprise, for example, elements illustrated in FIG. 8, such as an AC voltage and current generator 830, a digital control system implemented at least in part by computer 810, a transmit switching circuit including transmit switch(es) 840, a receive switching circuit including receive switch(es) 860, a multi-channel receive circuit including, e.g., a plurality of induction coils 850, preamplifier(s) 870, a digital acquisition system including AD converter(s) 820, a digital storage device which may be implemented within computer 810 or other digital storage device, and a digital computer 810 equipped with pulse sequence control software and/or SNMR processing software. The switching circuits may transition a system such as 800 between a transmit-mode, when the coil(s) 850 are connected to the transmit circuit and receive-mode when the coil(s) 850 are connected to the receive circuit. In a single acquisition sequence, the transmit circuit directs an AC current pulse or pulses with controlled amplitude and phase (alternating at the Larmor frequency) through the induction coil(s) 850 in short succession. As quickly as possible after a given transmit pulse, and before the next pulse, the switching circuits may transfer the induction coil(s) 850 into a single- or multi-channel receive circuit. The data acquisition system may then record the voltages on the receive circuit (including the surface coil(s) 850) and may record this received NMR signal data following the transmit pulse on the digital storage device. To form a complete cycled set, an acquisition sequence may be repeated one or more times, changing the phase of one or more transmit pulses between each acquisition sequence. After a complete cycled set corresponding to an NMR measurement is acquired, the signals recorded from each acquisition sequence may be linearly combined through digital processing.

In general, a SNMR measurement may be collected by transmitting one or more pulses of alternating current through a wire loop on the Earth's surface. The alternating current may be tuned to the Larmor frequency of hydrogen nuclei and may generate a magnetic field in the subsurface beneath the coil(s) alternating at the Larmor frequency. The alternating magnetic field radiates into the Earth and modifies the nuclear magnetization state of hydrogen present in fluids at depth. At equilibrium, the net nuclear magnetization is aligned with Earth's background magnetic field along the so-called longitudinal axis. The transmitted alternating magnetic field perturbs the magnetization from this equilibrium alignment so that some component of the nuclear magnetization rotates into the transverse “xy” plane. Once rotated from equilibrium, the magnetization relaxes over time back to the equilibrium state over time, decaying from the transverse plane and re-growing along the longitudinal axis. The rotation of the magnetization by the transmitted pulse(s) and subsequent relaxation to equilibrium are described by the phenomenological Bloch equations. The evolution of the magnetization under the Bloch equations depends on several variables including the amplitude of the transmitted field, the duration and timing of the transmitted field, the phase of the transmitted field, the longitudinal relaxation time T1, FID relaxation rate T2*, and/or the spin-spin relaxation time T2 of the hydrogen nuclei under investigation.

An NMR signal is generated by the presence of coherent transverse magnetization following a transmit pulse. The transverse magnetization generates a magnetic field, which oscillates at the Larmor frequency, and generally has a phase related to the phase of one or more of the transmitted pulses. The SNMR instrumentation records the NMR signal by monitoring the voltage on the surface loop. Identical measurements may be repeated to improve signal to noise; measurements using varied transmit currents may be used to modulate the contribution of signals from groundwater at different depths. Spatial inversion techniques may be used to isolate NMR signal contributions from different depth ranges or different locations in a 2D or 3D model of the subsurface, as described in U.S. Pat. No. 7,466,128.

Measurement schemes with one or more excitation pulses may be used to probe different types of NMR responses and properties. In a single pulse measurement, a single pulse rotates a component of the magnetization into the transverse plane. The signal produced as this coherent transverse magnetization relaxes to equilibrium is called the Free Induction Decay (FID) signal. In the single pulse sequence, the pulse sequence is repeated only after a delay period that is sufficiently long to allow the longitudinal relaxation process of liquid hydrogen samples in the subsurface to relax to their steady state. The FID signal can be used to determine the quantity of subsurface water content and the effective transverse relaxation time T2*. Double pulse sequences may be used to probe other relaxation times, such as T1 and/or T2. The first pulse rotates a component of the magnetization into the transverse plane; a second pulse transmitted after a controlled delay further modifies and rotates the magnetization state so that the recorded signal following the second pulse contains information about the decay times T1 and/or T2.

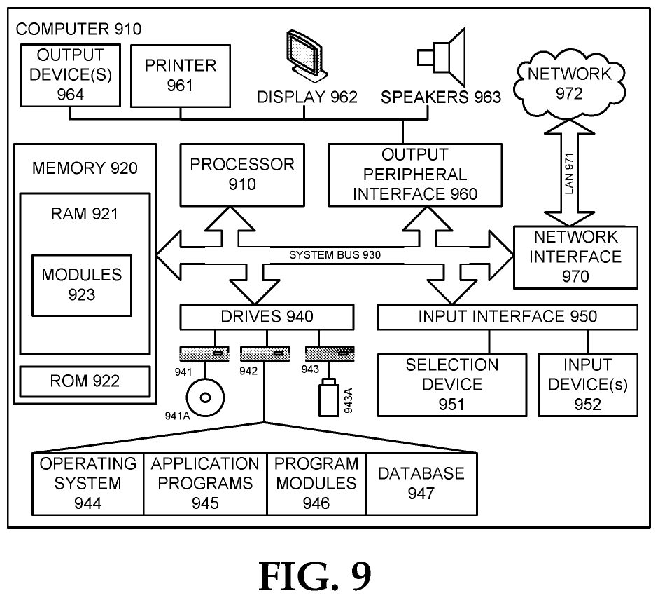

FIG. 9 is a block diagram illustrating an example computer, in accordance with various aspects and embodiments of the subject disclosure. The example computer 910 can implement the computer 810 introduced in FIG. 8. As discussed in connection with FIG. 8, the computer 910 may be configured to produce pulse sequences, to receive and record resulting NMR signal data, and/or to perform processing of NMR signal data.

Computing device 910 may include for example a processor 910, memory 920, system bus 930, one or more drives 940, user input interface 950, output peripheral interface 960, and network interface 970. Drives 940 may include, for example, a compact disk drive 941 which accepts an optical disk 941A, a so-called hard drive 942, which may employ any of a diverse range of computer readable media, and a flash drive 943 which may employ for example a Universal Serial Bus (USB) type interface to access a flash memory 943A. Drives may further include network drives and virtual drives (not shown) accessed via the network interface 970.

The drives 940 and their associated computer storage media provide storage of computer readable instructions, data structures, program modules and other data for the computer system 910. For example, a hard drive 942 may include an operating system 944, application programs 945, program modules 946, and database 947. Software aspects of the technologies described herein may be implemented, in some embodiments, as computer readable instructions stored on any of the drives 940 or on network 972, which instructions may be loaded into memory 920, for example as modules 923, and executed by processor 910.

Computer system 910 may further include a wired or wireless input interface 950 through which selection devices 951 and input devices 952 may interact with the other elements of the system 910. Selection devices 951 and input devices 952 can be connected to the input interface 950 which is in turn coupled to the system bus 930, allowing devices 951 and 952 to interact with processor 910 and the other elements of the system 910. Interface and bus structures that may be utilized to implement 950 may include for example a Peripheral Component Interconnect (PCI) type interface, parallel port, game port and a wired or wireless Universal Serial Bus (USB) interface.

Selection devices 951 such as a mouse, trackball, touch screen, or touch pad allow a user to select among desired options and/or data views that may be output by the computer 910, for example via the display 962. Input devices 952 can include any devices through which commands and data may be introduced to the computer 910. For example, in some embodiments the AD converter(s) 120 may be coupled to the computer 910 as an input device 952, and data received from the AD converter(s) 120 may be stored in drives 940. Other example input devices 952 include a keyboard, an electronic digitizer, a microphone, a joystick, game pad, satellite dish, scanner, media player, mobile device, or the like.

Computer system 910 may also include an output peripheral interface 960 which allows the processor 910 and other devices coupled to bus 930 to interact with output devices such as the function generators 811, 812, the AC voltage/current generator(s) 830, the transmit switches 840, the receive switches 860, and optionally a Digital to Analog (DA) converter as discussed further herein. Other example output devices include printer 961, display 962, and speakers 963. Interface and bus structures that may be utilized to implement 960 include those structures that can be used to implement the input interface 950. It should also be understood that many devices are capable of supplying input as well as receiving output, and input interface 950 and output interface 960 may be dual purpose or support two-way communication between components connected to the bus 930 as necessary.

Computing system 910 may operate in a networked environment using logical connections to one or more computers. By way of example, FIG. 9 shows a LAN 971 connection to a network 972. A remote computer may also be connected to network 971. The remote computer may be a personal computer, a server, a router, a network PC, a peer device or other common network node, and can include many or all of the elements described above relative to computing system 910. Networking environments are commonplace in offices, enterprise-wide area networks (WAN), local area networks (LAN), intranets and the Internet.

When used in a LAN or WLAN networking environment, computing system 910 is connected to the LAN through a network interface 970 or an adapter. When used in a WAN networking environment, computing system 910 typically includes a modem or other means for establishing communications over the WAN, such as the Internet or network 972. It will be appreciated that other means of establishing a communications link between computers may be used.

In some embodiments, computing system 910 may include modules 946 and/or 923 comprising, inter alia, one or more SNMR acquisition modules, and one or more SNMR signal data processing modules. The SNMR acquisition modules may be configured to control transmitting of two or more electrical current pulse sequences on induction coils arrangeable on or above the surface of the Earth. For example, the SNMR acquisition modules may be configured to control the phases of pulses with each pulse sequence, the time between pulses, the number of pulses, the number of pulse sequences, and the time between pulse sequences. The SNMR acquisition modules may be configured receive a pulse sequence selection or configuration from a user input, and may control the two or more electrical current pulse sequences according to the user selection. The SNMR acquisition modules may be configured to send control signals to the various devices illustrated in FIG. 8 to control pulse sequence transmission.

In some embodiments, the SNMR acquisition modules may also be configured to control receiving and recording signal data received in response to transmitted pulse sequences. For example, the SNMR acquisition modules may be configured to operate receive switches 860, to place the SNMR system 800 in a receive mode to detect signals on the induction coils after and/or during each of the electrical current pulse sequences. Detected signals may be converted to signal data by the AD converter(s) 820, and the signal data may be recorded in a memory of the computing device 910 or elsewhere.

In some embodiments, SNMR processing modules may be configured to linearly combine detected signal data corresponding to separate electrical current pulse sequences to produce combined signal data in which one or more detected signal components are preserved and one or more different detected signal components are reduced or cancelled. The preserved signal components may comprise, for example, NMR signal data, such as desired NMR data, and the reduced or cancelled signal components may comprise undesired NMR signal data and/or non-NMR signal data. Alternatively, the preserved signal components comprise undesired NMR signal data and/or non-NMR signal data, the reduced or cancelled signal components comprise NMR signal data. SNMR processing modules may be configured to process NMR data that is acquired according to the SNMR acquisition techniques discussed herein.

There is little distinction left between hardware and software implementations of aspects of systems; the use of hardware or software is generally (but not always) a design choice representing cost vs. efficiency tradeoffs. There are various vehicles by which processes and/or systems and/or other technologies described herein can be effected (e.g., hardware, software, and/or firmware), and that the preferred vehicle may vary with the context in which the processes and/or systems and/or other technologies are deployed. For example, if an implementer determines that speed and accuracy are paramount, the implementer may opt for a mainly hardware and/or firmware vehicle; if flexibility is paramount, the implementer may opt for a mainly software implementation; or, yet again alternatively, the implementer may opt for some combination of hardware, software, and/or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and or firmware would be within the skill of one skilled in the art in light of this disclosure. In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Video Disk (DVD), a digital tape, a computer memory, etc.; and a transmission type medium such as a digital and/or an analog communication medium (e.g., a fiber optic cable, a waveguide, a wired communications link, a wireless communication link, etc.).

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical data processing system may be implemented utilizing any suitable commercially available components, such as those typically found in data computing/communication and/or network computing/communication systems. The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermediate components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

While various embodiments have been disclosed herein, other aspects and embodiments will be apparent to those skilled in art.

1. A surface nuclear magnetic resonance (SNMR) measurement apparatus, comprising:
equipment adapted to apply an NMR response stimulating magnetic field in a sample volume, wherein the sample volume is under an Earth surface or within an engineered flow management structure, and wherein the NMR response stimulating magnetic field stimulates an NMR precession response in a fluid within the sample volume;
equipment adapted to detect and record an NMR response signal emitted from the sample volume in response to the NMR response stimulating magnetic field; and
equipment adapted to apply a switched gradient field in the sample volume, wherein the switched gradient field is configured to produce a phase, frequency, or slice encoding effect on the NMR response signal, and wherein the phase, frequency, or slice encoding effect on the NMR response signal can be used for spatial localization of the NMR response signal.

2. The SNMR measurement apparatus of claim 1, wherein the NMR response stimulating magnetic field comprises only a prepolarizing magnetic field without an NMR excitation pulse.

3. The SNMR measurement apparatus of claim 2, wherein the prepolarizing magnetic field is terminated non-adiabatically.

4. The SNMR measurement apparatus of claim 1, wherein the NMR response stimulating magnetic field comprises an NMR excitation pulse.

5. The SNMR measurement apparatus of claim 4, wherein the SNMR measurement apparatus further comprises equipment adapted to apply a prepolarizing magnetic field in the sample volume.

6. The SNMR measurement apparatus of claim 1, wherein the equipment adapted to apply the NMR response stimulating magnetic field comprises an SNMR coil, wherein the equipment adapted to detect and record the NMR response signal also comprises the SNMR coil, and the equipment adapted to apply the switched gradient field comprises a switchable gradient field generation element separate from the SNMR coil.

7. The SNMR measurement apparatus of claim 6, wherein the SNMR measurement apparatus comprises:
a transmitter, comprising:
transmit and receive connections adapted to connect with the SNMR coil; and
a communication connection adapted to communicatively couple the transmitter with a switched field module, wherein the switched field module comprises transmit connections adapted to connect with the switchable gradient field generation element;
wherein the SNMR coil and the switchable gradient field generation element are arrangeable on the Earth surface or the engineered flow management structure;
wherein the transmitter is adapted to transmit the NMR response stimulating magnetic field via the SNMR coil;
wherein the transmitter is adapted to control the switched field module via the communication connection, to cause the switched field module to transmit the switched gradient field via the switchable gradient field generation element; and
wherein the transmitter is adapted to receive the NMR response signal via the SNMR coil.

8. The SNMR measurement apparatus of claim 7, wherein the switchable gradient field generation element comprises a switchable coil.

9. The SNMR measurement apparatus of claim 8, wherein the switchable coil is larger than the SNMR coil, and wherein the SNMR coil is positionable inside the switchable coil.

10. The SNMR measurement apparatus of claim 7, wherein the SNMR coil comprises a figure-8 coil, an elliptical coil, or a rectangular coil.

11. The SNMR measurement apparatus of claim 7, wherein the transmitter is further adapted to control the switched field module via the communication connection to cause the switched field module to transmit a prepolarization field via the switchable gradient field generation element.

12. The SNMR measurement apparatus of claim 6, wherein the switchable gradient field generation element comprises an electrode.

13. The SNMR measurement apparatus of claim 1, wherein the engineered flow management structure comprises a dam, a levee, a canal, a well casing, a pipeline, an annular space between a well casing or underground pipeline and an undisturbed earth formation, a slurry wall, a grout curtain, or a retaining wall.

14. A surface nuclear magnetic resonance (SNMR) measurement method, comprising:
applying an NMR response stimulating magnetic field in a sample volume, wherein the sample volume is under an Earth surface or within an engineered flow management structure, and wherein the NMR response stimulating magnetic field stimulates an NMR precession response in a fluid within the sample volume;
detecting and recording an NMR response signal emitted from the sample volume in response to the NMR response stimulating magnetic field; and
applying a switched gradient field in the sample volume, wherein the switched gradient field is configured to produce a phase, frequency, or slice encoding effect on the NMR response signal, and wherein the phase, frequency, or slice encoding effect on the NMR response signal can be used for spatial localization of the NMR response signal.

15. The SNMR measurement method of claim 14, wherein the NMR response stimulating magnetic field comprises only a prepolarizing magnetic field without an NMR excitation pulse.

16. The SNMR measurement method of claim 15, wherein the prepolarizing magnetic field is terminated non-adiabatically.

17. The SNMR measurement method of claim 14, wherein the NMR response stimulating magnetic field comprises an NMR excitation pulse.

18. The SNMR measurement method of claim 17, further comprising applying a prepolarizing magnetic field in the sample volume.

19. The SNMR measurement method of claim 14, wherein the NMR response stimulating magnetic field is applied using an SNMR coil, wherein the SNMR coil is also used to detect and record the NMR response signal, and wherein the switched gradient field is applied using a switchable coil separate from the SNMR coil.

20. The SNMR measurement method of claim 14, wherein the engineered flow management structure comprises a dam, a levee, a canal, a well casing, a pipeline, an annular space between a well casing or underground pipeline and an undisturbed earth formation, a slurry wall, a grout curtain, or a retaining wall.

21. The SNMR measurement method of claim 14, wherein applying the switched gradient field is performed after applying the NMR response stimulating magnetic field and before detecting and recording the NMR response signal in order to produce the phase encoding effect.

22. The SNMR measurement method of claim 14, wherein applying the switched gradient field is performed after applying the NMR response stimulating magnetic field and during detecting and recording the NMR response signal in order to produce the frequency encoding effect.

23. The SNMR measurement method of claim 14, wherein applying the switched gradient field is performed during applying the NMR response stimulating magnetic field and before detecting and recording the NMR response signal in order to enable slice encoding.
